(19) United States
(12) Patent Application Publication
(10) Pub. No.: US 2026/0222707 A1
(43) Pub. Date: Jul. 30, 2026

(54) IMAGE SENSOR

(71) Applicant: SAMSUNG ELECTRONICS CO., LTD., Suwon-si (KR)

(72) Inventor: Heesang Kwon, Suwon-si (KR)

(73) Assignee: SAMSUNG ELECTRONICS CO., LTD., Suwon-si (KR)

(21) Appl. No.: 19/436,278

(22) Filed: Dec. 30, 2025

(30) Foreign Application Priority Data
Jan. 24, 2025 (KR) 10-2025-0011896

(51) Int. Cl. H04N 25/771; H10F 39/00; H10F 39/18

(52) U.S. Cl. CPC H04N 25/771; H10F 39/014; H10F 39/18; H10F 39/802; H10F 39/803

(57) ABSTRACT

An image sensor includes a plurality of pixels, where each of the plurality of pixels includes a plurality of photodiodes, a plurality of transfer transistors, a floating diffusion region sharing the plurality of photodiodes and the plurality of transfer transistors, a dual conversion gain transistor connected to the floating diffusion region, and a capacitor connected to one end of the dual conversion gain transistor, where the capacitor includes a first insulator, the dual conversion gain transistor includes a second insulator, and in a first direction, a first thickness of the first insulator of the capacitor is different from a second thickness of the second insulator of the dual conversion gain transistor.

### CROSS-REFERENCE TO RELATED APPLICATION

This application is based on and claims priority to Korean Patent Application No. 10-2025-0011896, filed on January 24, 2025, in the Korean Intellectual Property Office, the disclosure of which is incorporated by reference herein in its entirety.

### BACKGROUND

The present disclosure relates to an image sensor, and more particularly, to an image sensor characterized by a thickness of an insulator of a capacitor for controlling a conversion gain of a pixel included in the image sensor.

An image sensor is a device that captures a two-dimensional or three-dimensional image of an object. The image sensor generates images of objects by using photodiodes that react to the intensity of light reflected from the object. Recently, with the advancement of complementary metal-oxide semiconductor (CMOS) technology, CMOS image sensors (CIS) using CMOS are being widely used. Recently, a technology to add a capacitor to a floating diffusion region has been developed to increase a dynamic range of the image sensor.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an image sensor that may be capable of more finely controlling a conversion gain based on a thickness an insulator of a capacitor connected to a floating diffusion region being different from a thickness of an insulator of an adjacent transistor.

Additional aspects will be set forth in part in the description which follows and, in part, will be apparent from the description, or may be learned by practice of the presented embodiments.

According to an aspect of an example embodiment, an image sensor may include a plurality of pixels, where each of the plurality of pixels includes a plurality of photodiodes, a plurality of transfer transistors, a floating diffusion region sharing the plurality of photodiodes and the plurality of transfer transistors, a dual conversion gain transistor connected to the floating diffusion region, and a capacitor connected to one end of the dual conversion gain transistor, where the capacitor includes a first insulator, the dual conversion gain transistor includes a second insulator, and in a first direction, a first thickness of the first insulator of the capacitor is different from a second thickness of the second insulator of the dual conversion gain transistor.

According to an aspect of an example embodiment, an image sensor may include a plurality of sub-pixels, a floating diffusion region sharing the plurality of sub-pixels, and a pixel circuit connected to the floating diffusion region, the pixel circuit configured to control a conversion gain of the floating diffusion region, reset the floating diffusion region, and output charges stored in the floating diffusion region, where the pixel circuit may include at least one capacitor connected to the floating diffusion region and including at least one first insulator, and at least one dual conversion gain transistor including at least one second insulator, and in the first direction, a thickness of the at least one first insulator is different from a thickness of the at least one second insulator.

According to an aspect of an example embodiment, an image sensor may include a substrate having a first surface and a second surface opposite to the first surface in a first direction, a metal-oxide semiconductor (MOS) capacitor on the second surface of the substrate, and a dual conversion gain transistor on the substrate, where the MOS capacitor and the dual conversion gain transistor are configured to control a conversion gain of a floating diffusion region of a pixel, the MOS capacitor includes a first insulator on the substrate, and a first gate electrode on the first insulator, the dual conversion gain transistor includes a second insulator on the substrate, and a second gate electrode on the second insulator, and in the first direction, a thickness of the first insulator is different from a thickness of the second insulator.

According to an aspect of an example embodiment, a method of manufacturing a capacitor and a dual conversion gain transistor may include forming a shallow trench isolation (STI) region and a deep trench isolation (DTI) region on a substrate, forming a first insulator layer on the substrate, applying a photoresist to a location where a capacitor is to be formed and etching the photoresist, removing the photoresist and forming a second insulator layer where the photoresist was removed, and forming gate electrodes on the STI region and the DTI region.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a block diagram of an image sensor according to one or more embodiments;

FIGS. 2A, 2B and 2C are diagrams illustrating implementation examples of pixel arrays corresponding to color filter arrays according to one or more embodiments;

FIG. 3 is a circuit diagram of a pixel included in an image sensor according to one or more embodiments;

FIG. 4 is a cross-sectional view illustrating a structure of a first capacitor and a dual conversion gain transistor, according to one or more embodiments;

FIG. 5 is a cross-sectional view illustrating a structure of a first capacitor and a dual conversion gain transistor, according to one or more embodiments;

FIG. 6 is a cross-sectional view illustrating a structure of a first capacitor and a dual conversion gain transistor, according to one or more embodiments;

FIG. 7 is a cross-sectional view illustrating a structure of a first capacitor and a dual conversion gain transistor, according to one or more embodiments;

FIGS. 8A and 8B are cross-sectional views illustrating a structure of a first capacitor and a dual conversion gain transistor, according to one or more embodiments;

FIG. 9 is a circuit diagram of a pixel included in an image sensor according to one or more embodiments;

FIG. 10 is a cross-sectional view illustrating a structure of a second capacitor, a third capacitor, and a second dual conversion gain transistor, according to one or more embodiments;

FIG. 11 is a cross-sectional view illustrating a structure of a second capacitor, a third capacitor, and a second dual conversion gain transistor, according to one or more embodiments;

FIG. 12 is a cross-sectional view illustrating a structure of a second capacitor, a third capacitor, and a second dual conversion gain transistor, according to one or more embodiments;

FIGS. 13A, 13B, 13C and 13D are cross-sectional views illustrating a method of manufacturing a capacitor and a dual conversion gain transistor, according to one or more embodiments; and

FIGS. 14A, 14B, 14C and 14D are cross-sectional views illustrating a method of manufacturing a capacitor and a dual conversion gain transistor according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

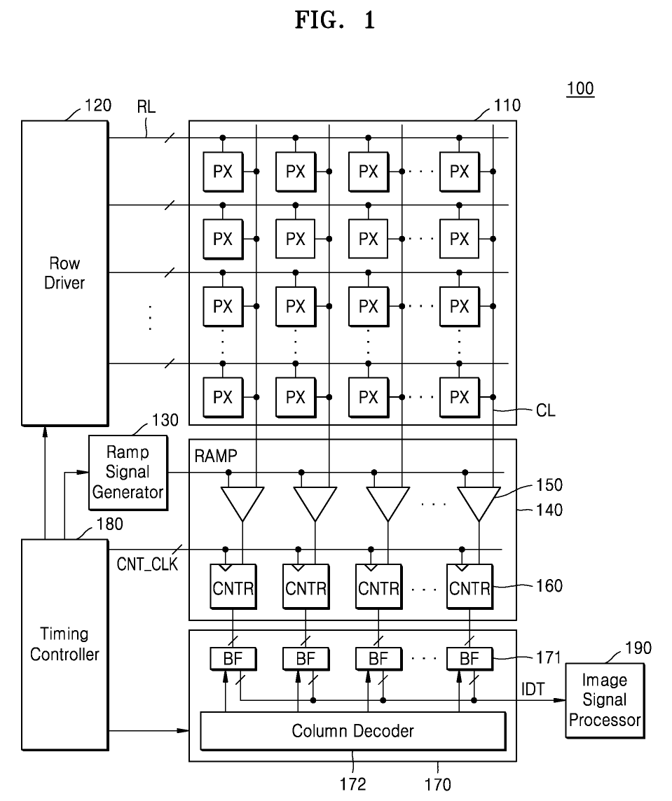

FIG. 1 is a block diagram of an image sensor according to one or more embodiments.

An image sensor 100 may be mounted on an electronic device having a function of sensing an image or light. For example, the image sensor 100 may be mounted on electronic devices such as cameras, smartphones, wearable devices, internet of things (IoT) devices, home appliances, tablet personal computers (PCs), personal digital assistants (PDAs), portable multimedia players (PMPs), navigation, drones, and advanced drivers assistance systems (ADAS). Additionally, the image sensor 100 may be mounted on electronic devices provided as components in vehicles, furniture, manufacturing equipment, doors, various measuring devices, etc.

Referring to FIG. 1, the image sensor 100 may include a pixel array 110, a row driver 120, a ramp signal generator 130, an analog-to-digital conversion circuit 140 (hereinafter referred to as an ADC circuit), a data output circuit 170, and a timing controller 180. The image sensor 100 may further include an image signal processor 190. A configuration including the ramp signal generator 130, the ADC circuit 140, and the data output circuit 170 may be referred to as a readout circuit.

The pixel array 110 may include a plurality of row lines RL, a plurality of column lines CL, and a plurality of pixels PX, the plurality of pixels PX being connected to the plurality of row lines RL and the plurality of column lines CL and arranged in rows and columns.

Each of the plurality of pixels PX may include a plurality of photodiodes, and the pixel PX may detect light using the photodiodes and output an image signal, which is an electrical signal depending on the detected light. For example, the photodiode may include a photodiode, a photo transistor, a photo gate, or a pinned photodiode.

Each of the plurality of pixels PX may detect light in a specific spectral range. For example, the plurality of pixels PX may include a red pixel for converting light in a red spectrum region into an electrical signal, a green pixel for converting light in a green spectrum region into an electrical signal, and a blue pixel for converting light in a blue spectrum region into an electrical signal. However, the plurality of pixels PX are not limited thereto, and may further include a white pixel. In one or more embodiments, the plurality of pixels PX may include pixels combined with different color configurations, such as yellow pixels, cyan pixels, and magenta pixels.

A color filter array may be arranged over the plurality of pixels PX to transmit light of a specific spectral range, and a color that the pixel may detect may be determined based on a color filter arranged over each of the plurality of pixels. However, embodiments are not limited thereto. In one or more embodiments, a certain photodiode may also convert light of a specific wavelength band into an electrical signal, depending on a level of the electrical signal applied to the photodiode.

In one or more embodiments, each of the plurality of pixels PX may have a dual conversion gain. The dual conversion gain may include a low conversion gain and a high conversion gain. Here, a conversion gain may refer to a rate at which charges accumulated in a floating diffusion region are converted into voltage. Charges generated in the photodiode are transferred to and accumulated in the floating diffusion region, and the charges accumulated in the floating diffusion region may be converted into voltage, depending on the conversion gain. In this case, the conversion gain may be varied depending on a capacitance of the floating diffusion region. As the capacitance increases, the conversion gain may decrease (low conversion gain), and as the capacitance decreases, the conversion gain may increase (high conversion gain). By increasing the capacitance of the floating diffusion region, a dynamic range may be improved.

In one or more embodiments, each of the plurality of pixels PX may have a triple conversion gain. The triple conversion gain may include a low conversion gain, a middle conversion gain, and a high conversion gain.

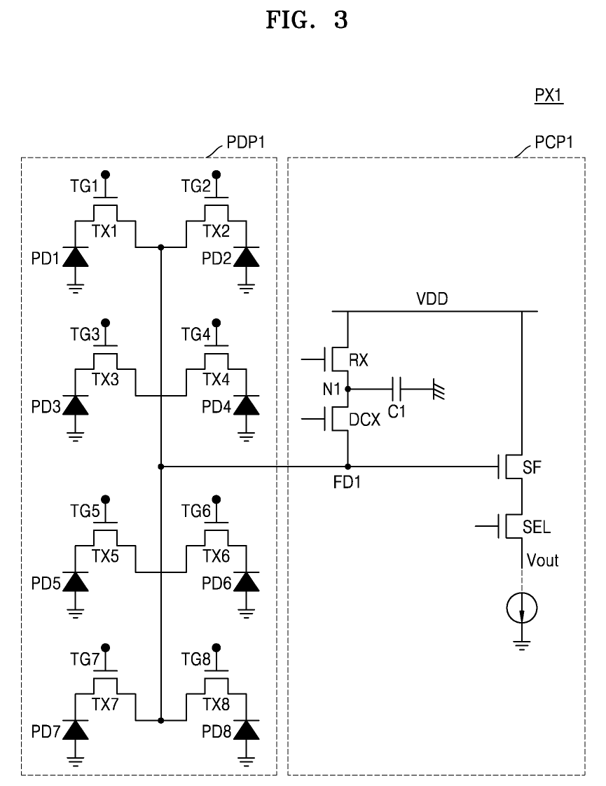

In one or more embodiments, the conversion gain of each of the plurality of pixels PX may be affected by a capacitance of the capacitor connected to the floating diffusion region. In one or more embodiments, by adjusting a thickness of an insulator of the capacitor connected to the floating diffusion region differently from a thickness of an insulator of the adjacent transistor, a conversion gain value may be adjusted more finely. According to one or more embodiments, by increasing or decreasing the thickness of the insulator of capacitor, the capacitance may be additionally adjusted, thereby reducing a dependence on capacitance adjustment by metal layout, enabling efficient layout design. This is described in more detail below in FIG. 3 and below.

The pixel PX according to one or more embodiments may include a plurality of sub-pixels, each of which may be connected to corresponding floating diffusion regions.

The row driver 120 drives the pixel array 110 in rows. The row driver 120 may decode a row control signal (e.g., an address signal) received from the timing controller 180 and select at least one row line among the row lines constituting the pixel array 110 in response to the decoded row control signal. For example, the row driver 120 may generate a selection signal to select one of a plurality of rows. In addition, the pixel array 110 outputs a pixel signal, for example, a pixel voltage, from a row selected by a selection signal provided from the row driver 120. The pixel signal may include a reset signal and an image signal. The row driver 120 may transmit control signals for outputting pixel signals to the pixel array 110, and the pixels PX may output pixel signals by operating in response to the control signals.

The ramp signal generator 130 may generate a ramp signal (e.g., ramp voltage) of which level rises or falls at a certain slope under a control of the timing controller 180. A ramp signal RAMP may be provided to each of a plurality of correlated double sampling (CDS) circuits 150 provided in the ADC circuit 140.

The ADC circuit 140 may include the plurality of CDS circuits 150 and a plurality of counters 160. The ADC circuit 140 may convert a pixel signal (e.g., pixel voltage) input from the pixel array 110 into a pixel value, which is a digital signal. Each pixel signal received through each of the plurality of column lines CL is converted into a pixel value, which is a digital signal, by the CDS circuit 150 and the counter 160.

The CDS circuit 150 may compare a pixel signal, such as a pixel voltage, received through a column line CL with the ramp signal RAMP and output the comparison result as a comparison result signal. The CDS circuit 150 may output a comparison signal that transitions from a first level (e.g., logic high) to a second level (e.g., logic low) when a level of the ramp signal RAMP and a level of the pixel signal are the same. A point at which the level of the comparison signal transitions may be determined depending on the level of the pixel signal.

The CDS circuit 150 may sample a pixel signal provided from the pixel PX according to a CDS method. The CDS circuit 150 may sample the reset signal received as the pixel signal, compare the reset signal with the ramp signal RAMP, and generate the comparison signal according to the reset signal. The CDS circuit may then sample an image signal correlated to the reset signal, compare the image signal with the ramp signal RAMP, and generate the comparison signal based on the image signal.

The counter 160 may count a level transition time of the comparison result signal output from the CDS circuit 150, based on a counting clock CNT_CLK provided from the timing controller 180 and output a count value.

In one or more embodiments, the counter 160 may be implemented as an up-counter and an operation circuit in which the count value sequentially increases based on the counting clock CNT_CLK, or an up/down counter, or a bit-wise inversion counter.

In one or more embodiments, the image sensor 100 may further include a counting code generator that generates a counting code (e.g., a gray code) of which value changes periodically and provides the counting code to each of the plurality of counters 160, and the counters 160 may include a latch circuit and an operation circuit. The latch circuit may latch a code value of the counting code at a point when a level of a counting comparison signal transitions. The latch circuit may latch each of a code value corresponding to the reset signal, such as a reset value, and a code value corresponding to an image signal, such as an image signal value. The operation circuit may generate an image signal value from which a reset level of the pixel PX is removed by calculating the reset value and the image signal value. The counter 160 may output the image signal value from which the reset level has been removed as a pixel value.

The data output circuit 170 may temporarily store and then output a pixel value output from the ADC circuit 140. The data output circuit 170 may include a plurality of column memories 171 (or referred to as buffers BF) and a column decoder 172. The column memory 171 stores the pixel value received from the corresponding counter 160. In one or more embodiments, each of the plurality of column memories 171 may be equipped with the counter 160. A plurality of pixel values stored in the plurality of column memories 171 may be output as image data IDTA under a control of the column decoder 172.

The timing controller 180 may control the operation or timing of the row driver 120, the ramp signal generator 130, the ADC circuit 140, and the data output circuit 170 by outputting a control signal to each of the row driver 120, the ramp signal generator 130, the ADC circuit 140, and the data output circuit 170.

The image signal processor 190 may perform noise reduction processing, gain adjustment, waveform standardization processing, interpolation processing, white balance processing, gamma processing, edge emphasis processing, binning, etc. on the image data IDTA. In one or more embodiments, the image signal processor 190 may be provided in an external processor located outside the image sensor 100.

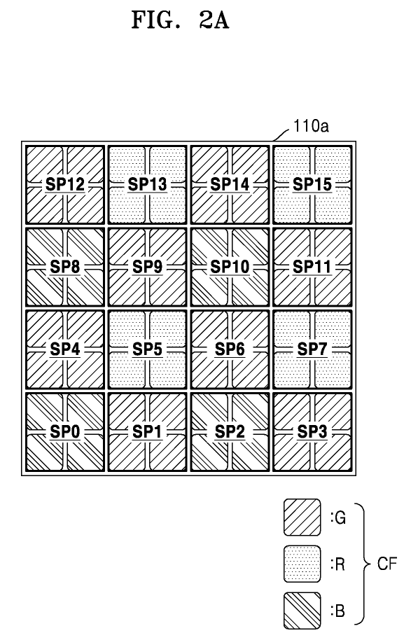

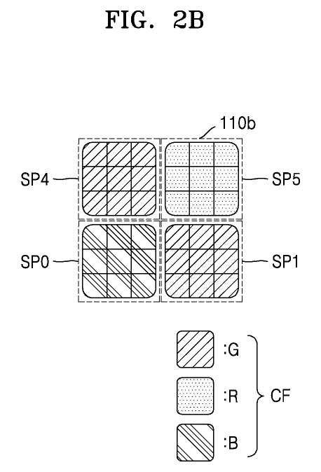

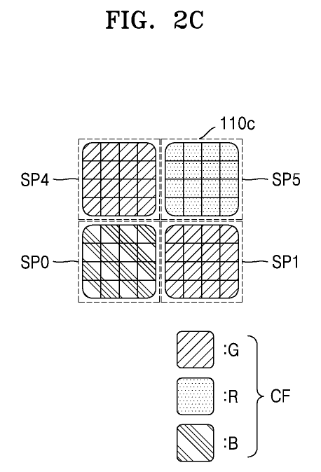

FIGS. 2A, 2B and 2C are diagrams illustrating implementation examples of pixel arrays corresponding to color filter arrays according to one or more embodiments.

Referring to FIG. 2A, a pixel array 110a may include a plurality of pixels arranged in a plurality of rows and columns. For example, a shared pixel defined as a unit including pixels arranged in two rows and two columns, may each include four sub-pixels. In other words, the shared pixel may include four photodiodes, each corresponding to one of four sub-pixels. The pixel array 110a may include first to sixteenth shared pixels SP0 to SP15. The pixel array 110a may include a color filter so that the shared pixels SP0 to SP15 may sense various colors. In one or more embodiments, the color filter may include filters for sensing red R, green G, and blue B, and one shared pixel SP0 to SP15 may include sub-pixels on which the same color filter is arranged. For example, the first shared pixel SP0, the third shared pixel SP2, the ninth shared pixel SP8, and the eleventh shared pixel SP10 may include sub-pixels having a blue B color filter. The second shared pixel SP1, the fourth shared pixel SP3, the fifth shared pixel SP4, the seventh shared pixel SP6, the tenth shared pixel SP9, the twelfth shared pixel SP11, the thirteenth shared pixel SP12, and the fifteenth shared pixel SP14 may include sub-pixels having a green G color filter. The sixth shared pixel SP5, the eighth shared pixel SP7, the fourteenth shared pixel SP13, and the sixteenth shared pixel SP15 may include sub-pixels having a red R color filter. Additionally, a group including the first shared pixel SP0, the second shared pixel SP1, the fifth shared pixel SP4, and the sixth shared pixel SP5, a group including the third shared pixel SP2, the fourth shared pixel SP3, the seventh shared pixel SP6, and the eighth shared pixel SP7, a group including the ninth shared pixel SP8, the tenth shared pixel SP9, the thirteenth shared pixel SP12, and the fourteenth shared pixel SP13, and a group including the eleventh shared pixel SP10, the twelfth shared pixel SP11, the fifteenth shared pixel SP14, and the sixteenth shared pixel SP15 may each be arranged in the pixel array 110a so as to correspond to a Bayer pattern. In one or more embodiments, a group including the first shared pixel SP0, the second shared pixel SP1, the fifth shared pixel SP4, and the sixth shared pixel SP5, a group including the third shared pixel SP2, the fourth shared pixel SP3, the seventh shared pixel SP6, and the eighth shared pixel SP7, a group including the ninth shared pixel SP8, the tenth shared pixel SP9, the thirteenth shared pixel SP12, and the fourteenth shared pixel SP13, and a group including the eleventh shared pixel SP10, the twelfth shared pixel SP11, the fifteenth shared pixel SP14, and the sixteenth shared pixel SP15 may each correspond to a color filter array (CFA) block.

However, embodiments are not limited thereto, and the pixel array 110a according to one or more embodiments may include various types of color filters. For example, the color filter may include filters for sensing yellow, cyan, magenta and green colors. Alternatively, the color filters may include filters that sense red, green, blue, and white colors. Additionally, the pixel array 110a may include more shared pixels, and the arrangement of each shared pixel SP0 to SP15 may be implemented in various ways.

Referring to a pixel array 110b of FIG. 2B, each shared pixel SP0, SP1, SP4, and SP5 may include 9 sub-pixels. The first shared pixel SP0 may include 9 sub-pixels having a blue B color filter, and the second shared pixel SP1 and the fifth shared pixel SP4 may each include 9 sub-pixels having the green G color filter. The sixth shared pixel SP5 may include 9 sub-pixels having the red R color filter. In one or more embodiments, the shared pixels SP0, SP1, SP4, and SP5 may be referred to as nona cells.

Referring to a pixel array 110c of FIG. 2C, each shared pixel SP0, SP1, SP4, and SP5 may include 16 sub-pixels. The first shared pixel SP0 may include 16 sub-pixels having the blue B color filter, and the second shared pixel SP1 and the fifth shared pixel SP4 may each include 16 sub-pixels having the green G color filter. The sixth shared pixel SP5 may include 16 sub-pixels having the red R color filter. In one or more embodiments, the shared pixels SP0, SP1, SP4, and SP5 may be referred to as a hexadica cell.

FIG. 3 is a circuit diagram of a pixel included in the image sensor according to one or more embodiments. According to one or more embodiments, a pixel PX1 of FIG. 3 may be the pixel PX included in the image sensor 100 of FIG. 1.

Referring to FIG. 3, the pixel PX1 may include a photodiode region PDP1 and a pixel circuit portion PCP1 connected to the photodiode region PDP1. The photodiode region PDP1 may include a plurality of photodiodes PD1 to PD8 and a plurality of transfer transistors TX1 to TX8, and the pixel circuit portion PCP1 may include a plurality of pixel transistors RX, DCX, SF, and SEL and a first capacitor C1 The photodiode region PDP1 and the pixel circuit portion PCP1 may be connected through a floating diffusion region FD1.

The pixel transistors RX, DCX, SF, and SEL of the pixel circuit portion PCP1 may include a reset transistor RX, a source follower transistor SF, a select transistor SEL, and a dual conversion gain transistor DCX, and the pixel circuit portion PCP1 may further include the first capacitor C1.

Although the pixel PX1 is disclosed as including 4 pixel transistors, it should be noted that embodiments are not limited thereto, and the number of pixel transistors included in each pixel PX1 may vary.

Each of the photodiodes PD1 to PD8 may generate and accumulate charges corresponding to incident light. Each of the photodiodes PD1 to PD8 may be, for example, a photodiode, a photo transistor, a photo gate, a pinned photodiode (PPD), or a combination thereof.

The transfer transistors TX1 to TX8 may transfer the charge accumulated in the photodiodes PD1 to PD8 to the floating diffusion region FD1. The transfer transistors TX1 to TX8 may be turned on or off by transfer signals TG1 toTG8 applied to the gates of the transfer transistors TX1 to TX8, respectively. One end of the plurality of transfer transistors TX1 to TX8 may be connected to the floating diffusion region FD1.

According to one or more embodiments, the pixel PX1 may include 8 photodiodes PD1 to PD8 and 8 transfer transistors TX1 to TX8, which may share one floating diffusion region FD1. In one or more embodiments, the pixel PX1 may include a plurality of sub-pixels each including one photodiode and one transfer transistor, and the plurality of sub-pixels may share the pixel circuit portion PCP1. In one or more embodiments, the pixel PX1 may include 8 sub-pixels, and the 8 sub-pixels may be arranged in a 2 x 4 array.

The floating diffusion region FD1 may receive and accumulate charges generated by the plurality of photodiodes PD1 to PD8. The source follower transistor SF may be controlled depending on the amount of photocharges accumulated in the floating diffusion region FD1.

The reset transistor RX may periodically reset charges accumulated in the floating diffusion region FD1 depending on a reset signal applied to a reset gate electrode. In more detail, the drain terminal of the reset transistor RX may be connected to the dual conversion gain transistor DCX, and the source terminal of the reset transistor RX may be connected to a power supply voltage VDD. When the reset transistor RX and the dual conversion gain transistor DCX are turned on, the power supply voltage VDD may be transferred to the floating diffusion region FD1. Accordingly, charges accumulated in the floating diffusion region FD1 may be discharged, and the floating diffusion region FD1 may be reset.

The dual conversion gain transistor DCX may be connected between the floating diffusion region FD1 and the reset transistor RX. The dual conversion gain transistor DCX may be connected in series with the reset transistor RX through a first node N1. The dual conversion gain transistor DCX may vary a conversion gain of the pixel PX1 by varying a capacitance of the floating diffusion region FD1 in response to a conversion gain control signal.

The first capacitor C1 may be connected to the first node N1. In one or more embodiments, the first capacitor C1 may be a metal-oxide-semiconductor (MOS) capacitor. The first capacitor C1 may be connected between one end of the reset transistor RX and one end of the dual conversion gain transistor DCX. The first capacitor C1 may be connected to one end of the dual conversion gain transistor DCX to increase the capacitance of the floating diffusion region FD1 as the dual conversion gain transistor DCX is turned on. The capacitance value of the first capacitor C1 may be affected by a thickness of an insulation of the first capacitor C1. In one or more embodiments, by making a thickness of the insulator of the first capacitor C1 different from the thickness of the insulator of the adjacent dual conversion gain transistor DCX, the capacitance value of the first capacitor C1 may be controlled to be higher or lower, thereby enabling the capacitance of the floating diffusion region FD1 to be controlled more precisely.

In detail, when capturing an image, low-light light and high-light light may be incident on the pixel array at the same time, or strong light and weak light may be incident on the pixel array at the same time. Accordingly, each pixel PX1 may have variable conversion gain depending on the incident light. The dual conversion gain transistor DCX is turned off so that the pixel PX1 may have a first conversion gain, and the dual conversion gain transistor DCX is turned on so that the pixel PX1 may have a second conversion gain that is less than the first conversion gain. Depending on the operation of the dual conversion gain transistor DCX, different conversion gains may be provided in the first conversion gain mode (or high-light mode) and the second conversion gain mode (or low-light mode).

When the dual conversion gain transistor DCX is turned off, the capacitance of the floating diffusion region FD1 may correspond to a first capacitance CFD1. When the dual conversion gain transistor DCX is turned on, the floating diffusion region FD1 is connected to the first node N1, so that the capacitance of the floating diffusion region FD1 may be the sum of the capacitance by the dual conversion gain transistor DCX and the capacitance by the first capacitor C1. In other words, when the dual conversion gain transistor DCX is turned on, the capacitance of the floating diffusion region FD1 increases, so that the conversion gain may be reduced, and when the dual conversion gain transistor DCX is turned off, the capacitance of the floating diffusion region FD1 decreases, so that the conversion gain may be increased. In this case, a capacitance value of the floating diffusion region FD1 and a value of the conversion gain may be adjusted by adjusting the thickness of the insulator of the first capacitor C1, thereby enabling more precise control of the conversion gain.

The source follower transistor SF may be a source follower buffer amplifier that generates a source-drain current proportional to the amount of charge of the floating diffusion region FD1 input to a source follower gate electrode. The source follower transistor SF amplifies the potential change at the floating diffusion region FD1 and outputs the amplified signal to an output line Vout through the select transistor SEL. A source terminal of the source follower transistor SF may be connected to the power supply voltage VDD, and a drain terminal of the source follower transistor SF may be connected to a source terminal of the select transistor SEL.

The select transistor SEL may select unit pixels to be read in a row unit. When the select transistor SEL is turned on by a selection signal applied to a selection gate electrode, an electrical signal output to the drain electrode of the source follower transistor SF may be output to the output line Vout.

According to one or more embodiments, when using the MOS capacitor to implement a multi-conversion gain, the conversion gain may be changed by controlling the capacitance by adding or deleting a separate insulator other than a gate oxide film of the transistor. In one or more embodiments, the total capacitance value at the floating diffusion region may be the sum of the capacitance due to the MOS capacitor, the capacitance due to a metal, and the capacitance due to a junction. According to one or more embodiments, because a capacitance value by the MOS capacitor is already determined, a capacitance by the metal is adjusted by changing a metal layer to control the total capacitance value, which affected a layout. According to one or more embodiments, the capacitance by the MOS capacitor may be controlled, thereby minimizing layout changes for securing or reducing the capacitance by the metal, thereby increasing an autonomy and freedom of the layout. Accordingly, a dependence of capacitance by the metal may be reduced. In addition, according to one or more embodiments, because the capacitance of the MOS capacitor may be varied more diversely than when using the same oxide film as the gate oxide of the transistor, a lower or higher conversion gain may be implemented with the same size of the MOS capacitor.

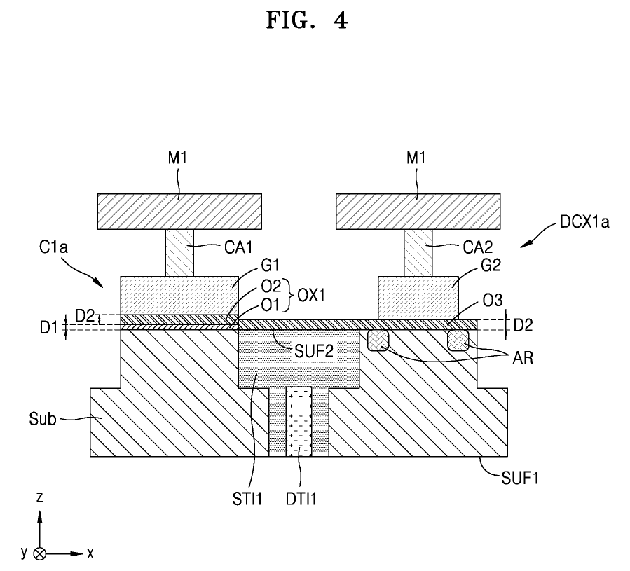

FIG. 4 is a cross-sectional view illustrating a structure of a first capacitor and a dual conversion gain transistor, according to one or more embodiments

Referring to FIG. 4, an example is illustrated in which a first capacitor C1a and a dual conversion gain transistor DCX1a are formed on a semiconductor substrate Sub. In one or more embodiments, the first capacitor C1a and the dual conversion gain transistor DCX1a illustrated in FIG. 4 may correspond to the first capacitor C1 and the dual conversion gain transistor DCX of FIG. 3, respectively.

Referring to FIG. 4, the first capacitor C1a may be provided in a structure of the MOS capacitor. In one or more embodiments, the first capacitor C1a may include the semiconductor substrate Sub, a first insulator structure OX1, and a first gate electrode G1.

The semiconductor substrate Sub may include a first surface SUF1 and a second surface SUF2 opposite to the first surface SUF1. According to one or more embodiments, the semiconductor substrate Sub may be a silicon substrate. In one or more embodiments, the semiconductor substrate Sub may include a semiconductor layer formed through an epitaxial process.

The first insulator structure OX1 may be placed on the semiconductor substrate Sub. In one or more embodiments, the first insulator structure OX1 may be a structure formed by stacking a first insulator O1 and a second insulator O2. In one or more embodiments, the first insulator structure OX1 may be a structure formed by stacking a plurality of insulators.

Referring to FIG. 4, the first insulator O1 and the second insulator O2 included in the first insulator structure OX1 may include different insulating materials. In one or more embodiments, the first insulator O1 and the second insulator O2 may include the same insulating material. In one or more embodiments, the first insulator O1 and the second insulator O2 may be insulators formed sequentially. In one or more embodiments, the first insulator O1 and the second insulator O2 may have a single-film or multi-film structure of at least one of, for example, a silicon oxide film, a silicon oxynitride film, a silicon nitride film, and a porous insulating film, but may not be limited thereto. In one or more embodiments, a thickness of the first insulator O1 may be D1, and a thickness of the second insulator O2 may be D2. Accordingly, a thickness of the first insulator structure OX1 may be D1+D2. In one or more embodiments, the thickness D1 of the first insulator O1 may be less than the thickness D2 of the second insulator O2, but may not be limited thereto.

The first gate electrode G1 may be placed on the first insulator structure OX1. The first gate electrode G1 and the semiconductor substrate Sub may serve as electrodes of the first capacitor C1a. A first contact area CA1 extending in a Z-axis direction may be connected to the first gate electrode G1, and a first metal layer M1 extending in an X-axis direction may be connected to the first contact area CA1.

Referring to FIG. 4, a center of the semiconductor substrate Sub may include a shallow trench isolation (STI) region STI1 and a deep trench isolation (DTI) region DTI1. A photoelectric conversion region may be arranged on the semiconductor substrate Sub, and the DTI region DTI1, which is a deep trench isolation region for isolation from an adjacent photoelectric conversion region, and the STI region STI1 for isolation between adjacent elements may be formed. The DTI region DTI1 may extend from a first surface SUF1 of the semiconductor substrate Sub to a certain depth, or may be formed to completely penetrate the semiconductor substrate Sub from the first surface SUF1 of the semiconductor substrate Sub to a second surface SUF2. Additionally, in one or more embodiments, the DTI region DTI1 may be formed from the second surface SUF2 of the semiconductor substrate Sub to a certain depth or may be formed completely penetrating the semiconductor substrate Sub. For example, the STI region STI1 and the DTI region DTI1 may include any insulating material such as silicon oxide (SiOx), silicon nitride (SiNx), or hafnium oxide (HfOx).

Referring to FIG. 4, the dual conversion gain transistor DCX1a may include an active region AR, a third insulator O3, and a second gate electrode G2 disposed on the third insulator O3. In one or more embodiments, the second gate electrode G2 may be connected to a second contact area CA2 extending in the Z-axis direction, and the second contact area CA2 may be connected to a first metal layer M1 extending in the X-axis direction. In one or more embodiments, the active region AR may be formed in the semiconductor substrate Sub and may include source/drain regions. The third insulator O3 may be placed on the semiconductor substrate Sub. According to one or more embodiments, a thickness of the third insulator O3 may be D2.

In one or more embodiments, the thickness of the third insulator O3 included in the dual conversion gain transistor DCX1a may be D2. In one or more embodiments, the thickness of the third insulator O3 may be the same as the thickness of the second insulator O2 included in the first insulator structure OX1. According to one or more embodiments, a material of the third insulator O3 may be the same as a material of the second insulator O2. According to one or more embodiments, the third insulator O3 and the second insulator O2 may be insulator layers formed in the same process.

In one or more embodiments, among the first insulator O1 and the second insulator O2, the second insulator O2 positioned in the upper portion may be provided with the same material and the same thickness as the third insulator O3.

Referring to FIG. 4, the thickness of the insulator of the dual conversion gain transistor DCX1a may be different from a thickness of the insulator of the first capacitor C1a. In one or more embodiments, a thickness D1+D2 of the insulator of the first capacitor C1a may have a value greater than a thickness D2 of the insulator of the dual conversion gain transistor DCX1a. Therefore, a capacitance value of the first capacitor C1a having a thickness of D1+D2 may be further reduced compared to a capacitance value of the capacitor having a thickness of the insulator of the dual conversion gain transistor DCX1a, i.e., D2.

Referring to FIG. 4, by adding a lower insulator to the first capacitor C1a, the capacitance value may be reduced, and through this, the capacitance value of the floating diffusion region in a low conversion gain mode in FIG. 3 may be controlled so that a smaller capacitance value is added, and through this, the first capacitor C1a may be controlled to have a desired capacitance value and a desired conversion gain.

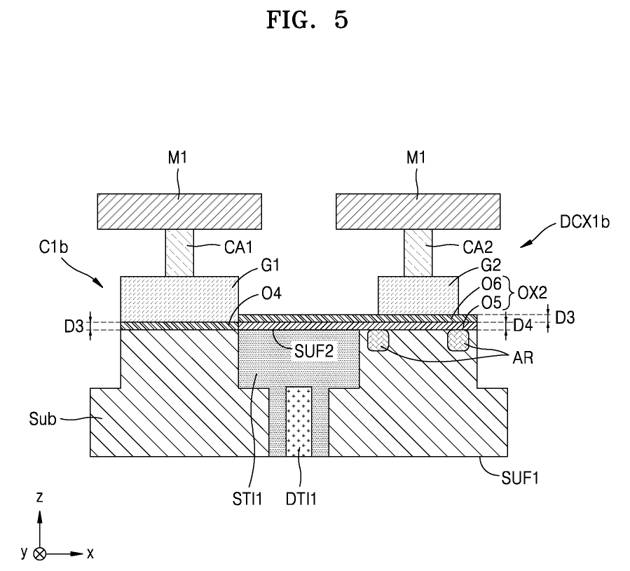

FIG. 5 is a cross-sectional view illustrating a structure of a first capacitor and a dual conversion gain transistor, according to one or more embodiments

Referring to FIG. 5, an example is illustrated in which a first capacitor C1b and a dual conversion gain transistor DCX1b are formed on a semiconductor substrate Sub. In one or more embodiments, the first capacitor C1b and the dual conversion gain transistor DCX1b illustrated in FIG. 5 may correspond to the first capacitor C1 and the dual conversion gain transistor DCX of FIG. 3, respectively.

Referring to FIG. 5, the first capacitor C1b may be provided in the structure of the MOS capacitor. In one or more embodiments, the first capacitor C1b may include the semiconductor substrate Sub, a fourth insulator O4, and the first gate electrode G1. The dual conversion gain transistor DCX1b may include the active region AR, a second insulator structure OX2, and the second gate electrode G2. In the description of FIG. 5, the same description may be applied to the same drawing symbols as those of the components of FIG. 4, so the description already given is omitted.

Referring to FIG. 5, the first capacitor C1b may include the fourth insulator O4. The fourth insulator O4 may be placed between the first gate electrode G1 and the semiconductor substrate Sub. A thickness of the fourth insulator O4 may be D3. In one or more embodiments, the fourth insulator O4 may have the single-film or multi-film structure of at least one of a silicon oxide film, a silicon oxynitride film, a silicon nitride film, and a porous insulating film, but may not be limited thereto.

Referring to FIG. 5, the second insulator structure OX2 may include a fifth insulator O5 and a sixth insulator O6. In one or more embodiments, the second insulator structure OX2 may be a structure formed by stacking the fifth insulator O5 and the sixth insulator O6. In one or more embodiments, the second insulator structure OX2 may be a structure formed by stacking a plurality of insulators. Referring to FIG. 5, the fifth insulator O5 and the sixth insulator O6 included in the second insulator structure OX2 may include different insulating materials from each other. In one or more embodiments, the fifth insulator O5 and the sixth insulator O6 may include the same insulating material. In one or more embodiments, the fifth insulator O5 and the sixth insulator O6 may have the single-film or multi-film structure of at least one of a silicon oxide film, a silicon oxynitride film, a silicon nitride film, and a porous insulating film, but may not be limited thereto. For example, according to one or more embodiments, a thickness of the fifth insulator O5 may be D4, and a thickness of the sixth insulator O6 may be D3. Accordingly, a thickness of the second insulator structure OX2 may be D3+D4.

In one or more embodiments, among the fifth insulator O5 and sixth insulator O6 of the second insulator structure OX2, the sixth insulator O6 positioned in an upper portion may be provided with the same material and the same thickness as the fourth insulator O4.

Referring to FIG. 5, a thickness of the insulator of the dual conversion gain transistor DCX1b may be different from a thickness of the insulator of the first capacitor C1b. In one or more embodiments, the thickness D3 of the insulator of the first capacitor C1b may have a value smaller than the thickness D3+D4 of the insulator of the dual conversion gain transistor DCX1b. Accordingly, a capacitance value of the first capacitor C1b having the thickness of D3 may further increase compared to a capacitance value of the capacitor having the thickness of the insulator of the dual conversion gain transistor DCX1b, i.e., D3+D4.

Referring to FIG. 5, by removing the lower insulator in the first capacitor C1b, the capacitance value may be increased, and through this, the capacitance value of the floating diffusion region in the low conversion gain mode in FIG. 3 may be controlled so that a greater capacitance value is added, and through this process, the desired capacitance value and the desired conversion gain may be controlled.

In FIGS. 4 and 5, it is described that the first capacitor may include an insulator structure and the dual conversion gain transistor may include one insulator, or the first capacitor may include one insulator and the dual conversion gain transistor may include the insulator structure, but one or more embodiments may not be limited thereto. In one or more embodiments, both the first capacitor and the dual conversion gain transistor may include an insulator structure, or both the first capacitor and the dual conversion gain transistor may include a single insulator layer. In this case, too, it is assumed that the thickness of the insulator of the first capacitor is different from the thickness of the insulator of the dual conversion gain transistor. In one or more embodiments, when both the first capacitor and the dual conversion gain transistor include the insulator structures, each insulator structure may include a plurality of stacked insulators, and a difference between the thickness of the first capacitor and the thickness of the dual conversion gain transistor may be determined based on the thickness of the insulator formed at the lowest position among the insulators included in each insulator structure.

In one or more embodiments, the first capacitor may include the first insulator and the second insulator stacked on the first insulator, and the dual conversion gain transistor may include the third insulator and the fourth insulator stacked on top of the third insulator. In this case, in FIG. 4, the second insulator and the fourth insulator may have the same thickness, and the thickness of the first insulator may be greater than the thickness of the third insulator. In FIG. 5, the second insulator and the fourth insulator may have the same thickness, and the thickness of the first insulator may be less than the thickness of the third insulator.

Additionally, in one or more embodiments, it is described that the thickness of the insulator of the first capacitor is different from the thickness of the insulator of the dual conversion gain transistor, but embodiments may be applied to other transistors included in the pixel in addition to the dual conversion gain transistor. For example, the thickness of the insulator of any one of the reset transistor, the select transistor, the source follower transistor, and the transfer transistor included in the pixel may be different from the thickness of the insulator of the first capacitor.

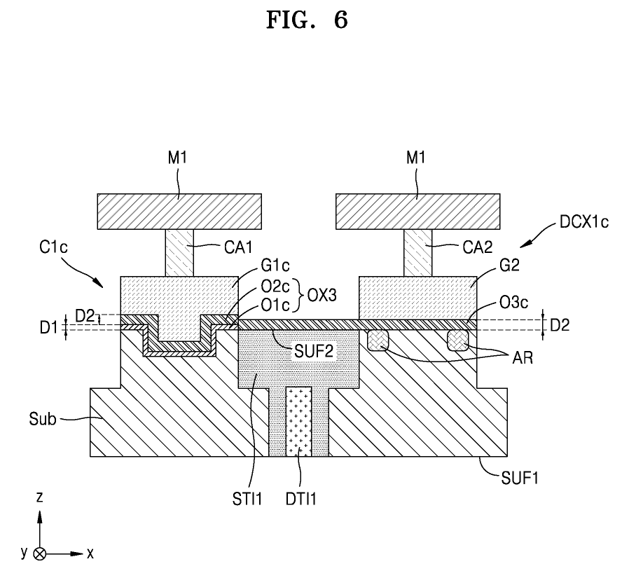

FIG. 6 is a cross-sectional view illustrating a structure of a first capacitor and a dual conversion gain transistor, according to one or more embodiments. Description of aspects that are the same as or similar to those described above may be omitted.

Referring to FIG. 6, an example is shown in which a first capacitor C1c and a dual conversion gain transistor DCX1c are formed on the semiconductor substrate Sub. In one or more embodiments, the first capacitor C1c and the dual conversion gain transistor DCX1c illustrated in FIG. 6 may correspond to the first capacitor C1 and the dual conversion gain transistor DCX of FIG. 3, respectively.

Referring to FIG. 6, the first capacitor C1c may be provided in the structure of the MOS capacitor. In one or more embodiments, the first capacitor C1c may include the semiconductor substrate Sub, a third insulator structure OX3, and the first gate electrode G1. The dual conversion gain transistor DCX1c may include an active region AR, a third insulator O3c, and the second gate electrode G2. .

The first capacitor C1c according to FIG. 6 may have a vertical transfer gate structure. In one or more embodiments, a first gate electrode G1c is provided in a vertical transfer gate structure and may be formed inside a recess extending from the second surface SUF2 of the semiconductor substrate Sub into the interior of the semiconductor substrate Sub. In one or more embodiments, a third insulator structure OX3 may be placed between the first gate electrode G1c and the semiconductor substrate Sub.

In one or more embodiments, the third insulator structure OX3 may include a first insulator O1c and a second insulator O2c, and the first insulator O1c and the second insulator O2c may be arranged in a stacked manner. In one or more embodiments, a thickness of the first insulator O1c may be D1, and a thickness of the second insulator O2c may be D2. A thickness of the third insulator O3c included in the dual conversion gain transistor DCX1c may be D2.

Referring to FIG. 6, the first capacitor C1c may be a MOS capacitor having a vertical transfer gate structure, and a thickness D1+D2 of the insulator of the first capacitor C1c may have a value greater than the insulator thickness D2 of the dual conversion gain transistor DCX1c.

In one or more embodiments, the thickness of the insulator of the first capacitor having the vertical transfer gate structure may have a value smaller than the insulator thickness of the dual conversion gain transistor.

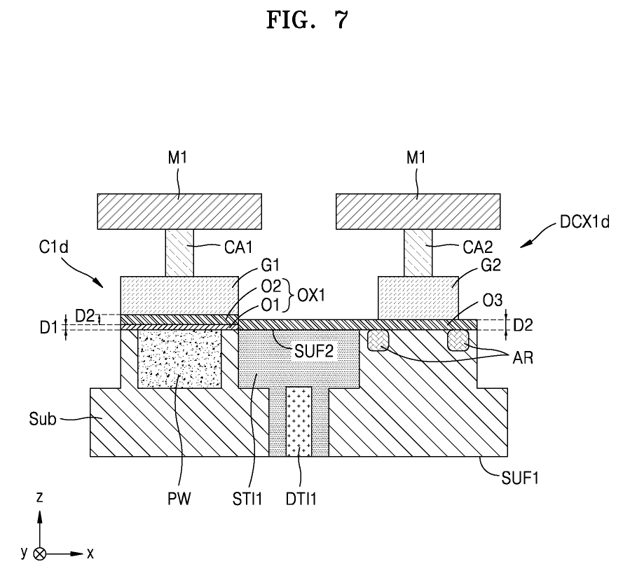

FIG. 7 is a cross-sectional view illustrating a structure of a first capacitor and a dual conversion gain transistor, according to one or more embodiments. Description of aspects that are the same as or similar to those described above may be omitted.

Referring to FIG. 7, an example is shown in which a first capacitor C1d and a dual conversion gain transistor DCX1d are formed on the semiconductor substrate Sub. In one or more embodiments, the first capacitor C1d and the dual conversion gain transistor DCX1d illustrated in FIG. 7 may correspond to the first capacitor C1 and the dual conversion gain transistor DCX of FIG. 3, respectively.

Referring to FIG. 7, the first capacitor C1d may be provided in the structure of the MOS capacitor. According to one or more embodiments, the first capacitor C1d may include the semiconductor substrate Sub, the first insulator structure OX1, and the first gate electrode G1. The dual conversion gain transistor DCX1d may include the active region AR, the third insulator O3, and the second gate electrode G2.

Referring to FIG. 7, the semiconductor substrate Sub of the first capacitor C1d may include a well region PW doped with a first conductivity type. In one or more embodiments, the first conductivity type may be P-type. In one or more embodiments, by adding a p-type well region to the semiconductor substrate Sub of the first capacitor C1d, a capacitance of the first capacitor C1d may be additionally controlled.

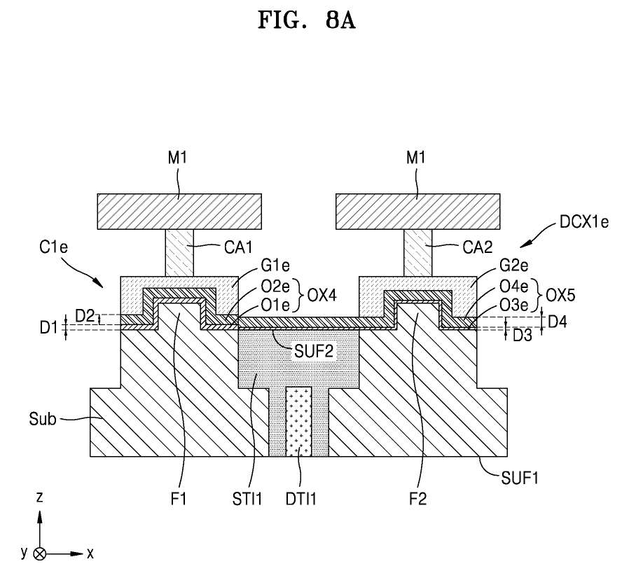

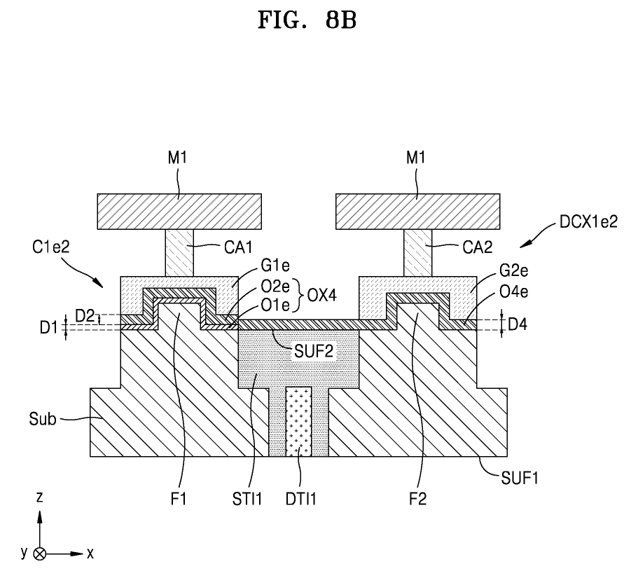

FIGS. 8A and 8B are cross-sectional views illustrating a structure of a first capacitor and a dual conversion gain transistor, according to one or more embodiments. Description of aspects that are the same as or similar to those described above may be omitted.

Referring to FIG. 8A, an example is illustrated in which a first capacitor C1e and a dual conversion gain transistor DCX1e are formed on the semiconductor substrate Sub. In one or more embodiments, the first capacitor C1e and the dual conversion gain transistor DCX1e illustrated in FIG. 8A may correspond to the first capacitor C1 and the dual conversion gain transistor DCX of FIG. 3, respectively.

Referring to FIG. 8A, the first capacitor C1e may be provided in the structure of the MOS capacitor. In one or more embodiments, the first capacitor C1e may include the semiconductor substrate Sub, a fourth insulator structure OX4, and a first gate electrode G1e. The dual conversion gain transistor DCX1e may include a fifth insulator structure OX5 and a second gate electrode G2e.

Referring to FIG. 8A, the first capacitor C1e and the dual conversion gain transistor DCX1e may be provided in a fin field-effect transistor (finFET) structure. In one or more embodiments, the FinFET structure may be formed by a fin-shaped active pattern extending in the Y-axis direction and gate electrodes G1e and G2e extending in the X-axis direction, between the STI regions. Source/drain regions may be formed on both sides of the second gate electrode G2e of the dual conversion gain transistor DCX1e, and thus the source and drain may be spaced apart from each other in the Y-axis direction. The fourth insulator structure OX4 may be placed between a fin region F1 and the second gate electrode G2e (similar positioning may be applied for the fifth insulator structure OX5 and the fin region F2).

The fourth insulator structure OX4 may be placed between the first gate electrode G1e of the first capacitor C1e and the semiconductor substrate Sub. In one or more embodiments, the fourth insulator structure OX4 may be a structure formed by stacking a first insulator O1e and a second insulator O2e. In one or more embodiments, a thickness of the first insulator O1e may be D1, and a thickness of the second insulator O2e may be D2. A thickness of the fourth insulator structure OX4 may be D1+D2.

In one or more embodiments, the fifth insulator structure OX5 included in the dual conversion gain transistor DCX1e may have a structure formed by stacking a third insulator O3e and a fourth insulator O4e. In one or more embodiments, a thickness of the third insulator O3e may be D3, and a thickness of the fourth insulator O4e may be D4. A thickness of the fifth insulator structure OX5 may be D3+D4.

In one or more embodiments, the thickness of the fourth insulator structure OX4 may be different from the thickness of the fifth insulator structure OX5. According to one or more embodiments, a thickness D1+D2 of the fourth insulator structure OX4 may be greater than a thickness D3+D4 of the fifth insulator structure OX5. According to one or more embodiments, a thickness D1 of the first insulator O1e may be greater than a thickness D3 of the third insulator O3e, and a thickness D2 of the second insulator O2e may be equal to a thickness D4 of the fourth insulator O4e.

Referring to FIG. 8B, an example is illustrated in which a first capacitor C1e2 and a dual conversion gain transistor DCX1e2 are formed on the semiconductor substrate Sub. In one or more embodiments, the first capacitor C1e2 and the dual conversion gain transistor DCX1e2 illustrated in FIG. 8B may correspond to the first capacitor C1 and the dual conversion gain transistor DCX of FIG. 3, respectively. In the description of FIG. 8B, the description already given in FIG. 8A may be omitted.

The fourth insulator structure OX4 may be placed between the first gate electrode G1e of the first capacitor C1e and the semiconductor substrate Sub. In one or more embodiments, the fourth insulator structure OX4 may be a structure formed by stacking the first insulator O1e and the second insulator O2e. In one or more embodiments, the thickness of the first insulator O1e may be D1, and the thickness of the second insulator O2e may be D2. The thickness of the fourth insulator structure OX4 may be D1+D2.

In one or more embodiments, the dual conversion gain transistor DCX1e2 may include the fourth insulator O4e. In one or more embodiments, the thickness of the fourth insulator O4e may be D4. In FIG. 8B, the thickness of the fourth insulator structure OX4 may be different from the thickness of the fourth insulator O4e. According to one or more embodiments, the thickness D1+D2 of the fourth insulator structure OX4 may be greater than the thickness D4 of the fourth insulator O4e. In one or more embodiments, an insulator of the dual conversion gain transistor DCX1e2 may be provided as a single layer.

Referring to FIGS. 8A and 8B, the first capacitors C1e and C1e2 and the dual conversion gain transistors DCX1e and DCX1e2 may have the FinFET structure, and under the FinFET structure, a thickness of the insulator of the first capacitors C1e and C1e2 may be different from a thickness of the insulator of the dual conversion gain transistors DCX1e and DCX1e2. In FIGS. 8A and 8B, an embodiment is shown in which the thickness of the insulator of the first capacitors C1e and C1e2 under the FinFET structure is thicker than the thickness of the insulator of the dual conversion gain transistors DCX1e and DCX1e2, but the thickness of the insulator of the first capacitors C1e and C1e2 under the FinFET structure may be provided to be less than the thickness of the insulator of the dual conversion gain transistors DCX1e and DCX1e2.

In FIGS. 6 to 8B, embodiments in which the thickness of insulator of the first capacitor is greater than the thickness of the insulator of the dual conversion gain transistor are illustrated and described, but the embodiments of FIGS. 6 to 8B may also be applied to the case in which the thickness of the insulator of the first capacitor is less than the thickness of the insulator of the dual conversion gain transistor.

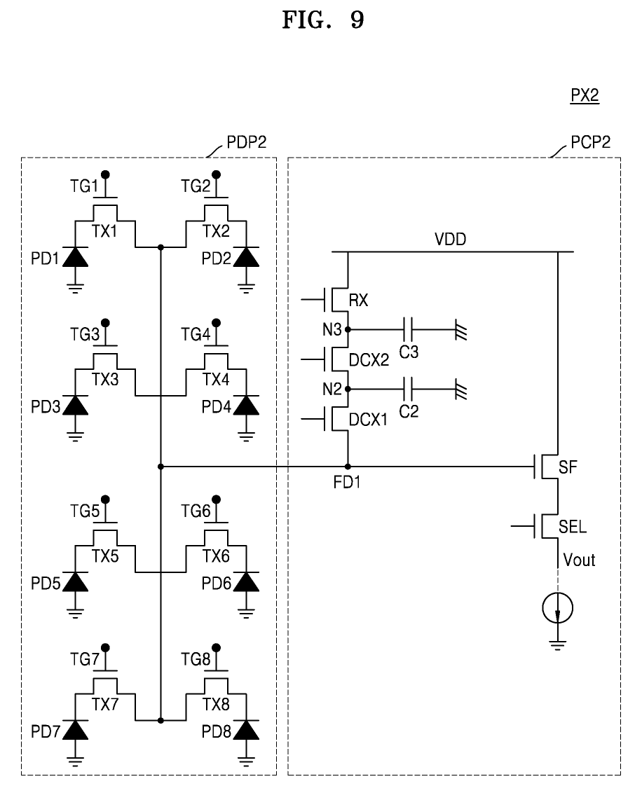

FIG. 9 is a circuit diagram of a pixel included in an image sensor according to one or more embodiments. According to one or more embodiments, a pixel PX2 of FIG. 9 may be a pixel PX included in the image sensor 100 of FIG. 1. Description of aspects that are the same as or similar to those described above may be omitted.

Referring to FIG. 9, the pixel PX2 may include a photodiode region PDP2 and a pixel circuit portion PCP2 connected to the photodiode region PDP2. The photodiode region PDP2 may include a plurality of photodiodes PD1 toPD8 and a plurality of transfer transistors TX1 to TX8, and the pixel circuit portion PCP2 may include a plurality of pixel transistors RX, SF, SEL, DCX1, and DCX2 and a plurality of capacitors C2 and C3. The photodiode region PDP2 and the pixel circuit portion PCP2 may be connected through a floating diffusion region FD2 from each other.

In one or more embodiments, because the configuration of the photodiode region PDP2 of the pixel PX2 is the same as the configuration of the photodiode region PDP1 of the pixel PX1 of FIG. 3, the description already given may be omitted.

The pixel transistors of the pixel circuit portion PCP2 may include the reset transistor RX, the source follower transistor SF, the select transistor SEL, a first dual conversion gain transistor DCX1, and a second dual conversion gain transistor DCX2. The pixel circuit portion PCP2 may further include a second capacitor C2 and a third capacitor C3.

The configuration of the reset transistor RX, the source follower transistor SF, and the selection transistor SEL among the pixel transistors included in the pixel circuit portion PCP2 is the same as the configuration of the reset transistor RX, the source follower transistor SF, and the selection transistor SEL of the pixel circuit portion PCP1 of FIG. 3, so the description already given is omitted.

The first dual conversion gain transistor DCX1, the second dual conversion gain transistor DCX2, and the reset transistor RX may be connected in series to the floating diffusion region FD2 of the pixel circuit portion PCP2. In one or more embodiments, the second capacitor C2 may be connected to a second node N2 between the first dual conversion gain transistor DCX1 and the second dual conversion gain transistor DCX2. The third capacitor C3 may be connected to a third node N3 between the second dual conversion gain transistor DCX2 and the reset transistor RX. Depending on whether the first dual conversion gain transistor DCX1 and the second dual conversion gain transistor DCX2 are turned on, a capacitance of the floating diffusion region FD2 may be changed, and a conversion gain of the pixel PX2 may be adjusted accordingly. In one or more embodiments, when the first dual conversion gain transistor DCX1 and the second dual conversion gain transistor DCX2 are turned off, the capacitance of the floating diffusion region FD2 may have the smallest value, and the pixel PX2 may operate in a high conversion gain mode. In one or more embodiments, when the first dual conversion gain transistor DCX1 is turned on and the second dual conversion gain transistor DCX2 is turned off, the capacitance of the floating diffusion region FD2 may be further increased by adding the value of the capacitance by the first dual conversion gain transistor DCX1 and the second capacitor C2, and the pixel PX2 may operate in a middle conversion gain mode. In one or more embodiments, when the first dual conversion gain transistor DCX1 and the second dual conversion gain transistor DCX2 are turned on, the capacitance of the floating diffusion region FD2 may have the greatest value by adding the values of the capacitances by the first dual conversion gain transistor DCX, the second dual conversion gain transistor DCX2, the second capacitor C2, and the third capacitor C3, and the pixel PX2 may operate in the low conversion gain mode.

The pixel PX2 may operate in three modes: high conversion gain mode, middle conversion gain mode, and low conversion gain mode. In the middle conversion gain mode and the low conversion gain mode, the conversion gain may be determined by the capacitances of the second capacitor C2 and the third capacitor C3. To obtain a desired conversion gain value, it may be necessary to finely adjust the capacitance values of the second capacitor C2 and the third capacitor C3. In one or more embodiments, the conversion gain may be controlled more finely in a multi-conversion gain control mode by controlling thicknesses of the insulators of the second capacitor C2 and the third capacitor C3. In one or more embodiments, the thickness of the insulator of the second capacitor C2 and the third capacitor C3 may be different from the thickness of the insulator of other pixel transistors included in the pixel circuit portion PCP2.

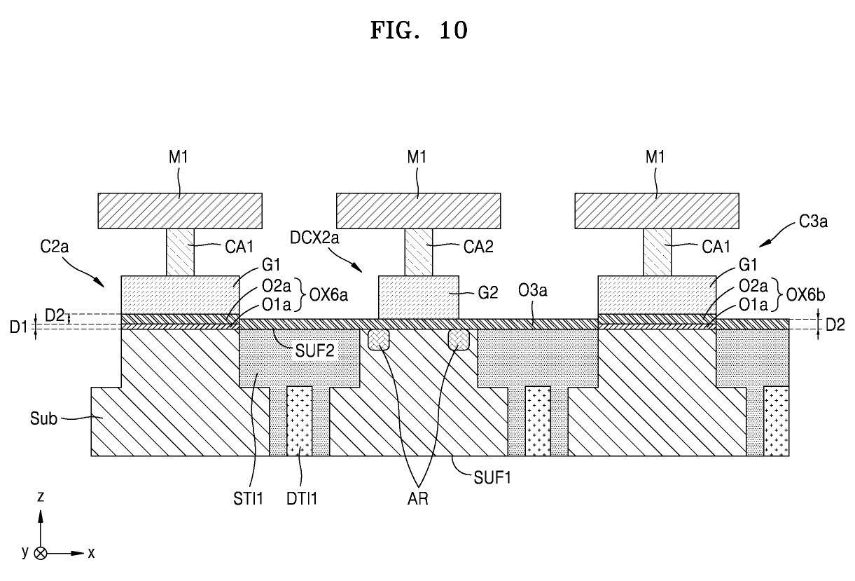

FIGS. 10 to 12 are cross-sectional views illustrating structures of the second capacitor, the third capacitor, and the second dual conversion gain transistor, according to one or more embodiments. Description of aspects that are the same as or similar to those described above may be omitted.

Referring to FIG. 10, a second capacitor C2a, a third capacitor C3a, and a second dual conversion gain transistor DCX2a may be formed on the semiconductor substrate Sub. In one or more embodiments, the second capacitor C2a, the third capacitor C3a, and the second dual conversion gain transistor DCX2a may correspond to the second capacitor C2, the third capacitor C3, and the second dual conversion gain transistor DCX2 of FIG. 9, respectively.

The second capacitor C2a and the third capacitor C3a may be provided in the structure of the MOS capacitor. The second capacitor C2a may include the first gate electrode G1, a sixth insulator structure OX6a, and the semiconductor substrate Sub. The third capacitor C3a may include the first gate electrode G1, a sixth insulator structure OX6b, and the semiconductor substrate Sub. The second dual conversion gain transistor DCX2a may include the second gate electrode G2, a third insulator O3a, and the active region AR. According to one or more embodiments, the sixth insulator structure OX6a and the sixth insulator structure OX6b may include a first insulator O1a and a second insulator O2a. A thickness of the first insulator O1a may be D1, and a thickness of the second insulator O2a may be D2. A thickness of the third insulator O3a may be D2.

In FIG. 10, a thickness of the insulator of the second capacitor C2a and a thickness of the insulator of the third capacitor C3a may be equal to D1+D2. In one or more embodiments, a thickness D1+D2 of the insulator of the second capacitor C2a and the third capacitor C3a may have a value greater than a thickness D2 of the insulation of the second dual conversion gain transistor DCX2a.

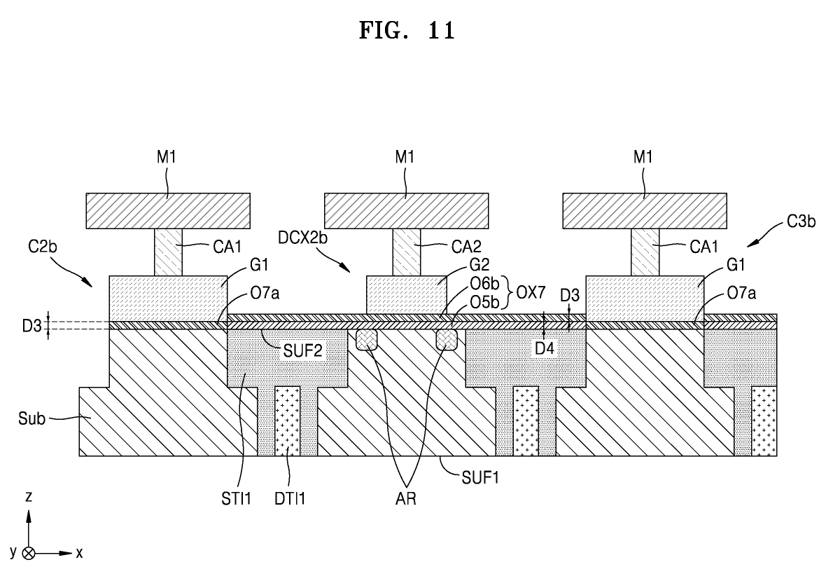

Referring to FIG. 11, a second capacitor C2b, a third capacitor C3b, and a second dual conversion gain transistor DCX2b may be formed on a semiconductor substrate Sub. In one or more embodiments, the second capacitor C2b, the third capacitor C3b, and the second dual conversion gain transistor DCX2b may correspond to the second capacitor C2, the third capacitor C3, and the second dual conversion gain transistor DCX2 of FIG. 9, respectively.

The second capacitor C2b and the third capacitor C3b may be provided in the structure of the MOS capacitor. The second capacitor C2b may include the first gate electrode G1, a first insulator O7a, and the semiconductor substrate Sub. The third capacitor C3b may include the first gate electrode G1, the first insulator O7a, and the semiconductor substrate Sub. The second dual conversion gain transistor DCX2b may include the second gate electrode G2, a seventh insulator structure OX7, and the active region AR. According to one or more embodiments, the seventh insulator structure OX7 may include a first insulator O5b and a second insulator O6b. A thickness of the first insulator O5b may be D4, and a thickness of the second insulator O6b may be D3. A thickness of the first insulator O7a may be D3.

According to one or more embodiments, a thickness of the insulator of the second capacitor C2b may be the same as a thickness of the insulator of the third capacitor C3b as D3. According to one example, a thickness D3 of the insulator of the second capacitor C2b and the third capacitor C3b may have a value smaller than a thickness D3+D4 of the insulator of the second dual conversion gain transistor DCX2a.

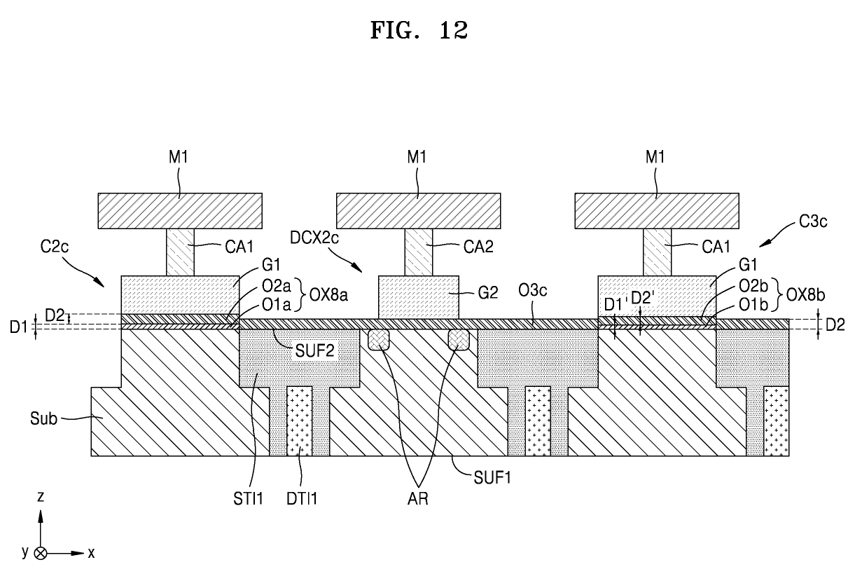

Referring to FIG. 12, a second capacitor C2c, a third capacitor C3c, and a second dual conversion gain transistor DCX2c may be formed on the semiconductor substrate Sub. In one or more embodiments, the second capacitor C2c, the third capacitor C3c, and the second dual conversion gain transistor DCX2c may correspond to the second capacitor C2, the third capacitor C3, and the second dual conversion gain transistor DCX2 of FIG. 9, respectively.

The second capacitor C2c and the third capacitor C3c may be provided in the structure of the MOS capacitor. The second capacitor C2c may include the first gate electrode G1, a first insulator structure OX8a, and the semiconductor substrate Sub. The third capacitor C3c may include the first gate electrode G1, a second insulator structure OX8b, and the semiconductor substrate Sub. The second dual conversion gain transistor DCX2c may include the second gate electrode G2, the third insulator O3a, and the active region AR. According to one or more embodiments, the first insulator structure OX8a may include the first insulator O1a and the second insulator O2a. According to one or more embodiments, the second insulator structure OX8b may include a first insulator O1b and a second insulator O2b. In one or more embodiments, the thickness of the first insulator O1a may be D1, and the thickness of the second insulator O2a may be D2. The thickness of the third insulator O3a may be D2. The thickness of the first insulator O1b may be D1’, and the thickness of the second insulator O2b may be D2’. According to one or more embodiments, a thickness D1+D2 of the insulator of the second capacitor C2c may be different from a thickness D1’+D2’ of the insulator of the third capacitor C3c. In one or more embodiments, the thickness D1+D2 of the insulator of the second capacitor C2c may have a value greater than the thickness D1’+D2’ of the insulator of the third capacitor C3c. In FIG. 12, an embodiment in which the thickness of the insulator of the second capacitor C2c is greater than the thickness of the insulator of the third capacitor C3c is described, but one or more embodiments may also be applied to a case in which the thickness of the insulator of the second capacitor C2c is less than the thickness of the insulator of the third capacitor C3c.

According to one or more embodiments, a thickness of the insulator of each of the plurality of capacitors connected to the floating diffusion region may be provided to be the same or different, and accordingly, the thickness of the insulator of each capacitor may be adjusted differently based on a calculated value to obtain a desired capacitance by the user.

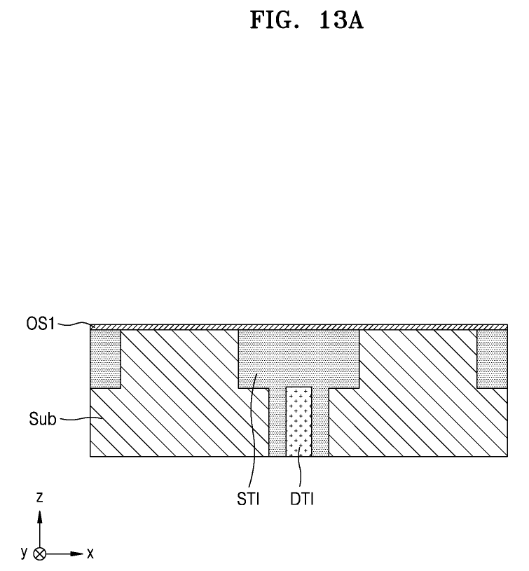

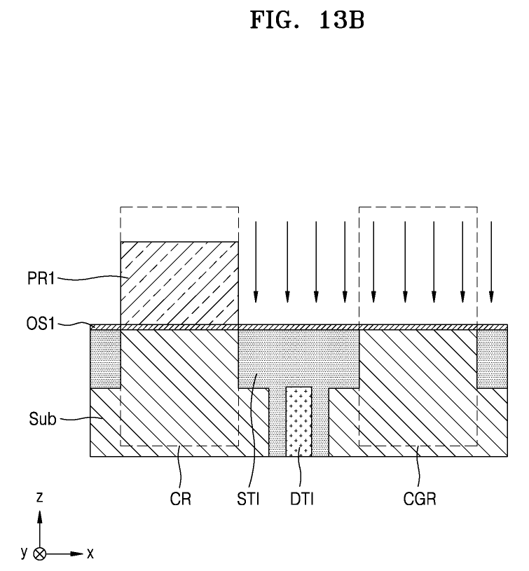

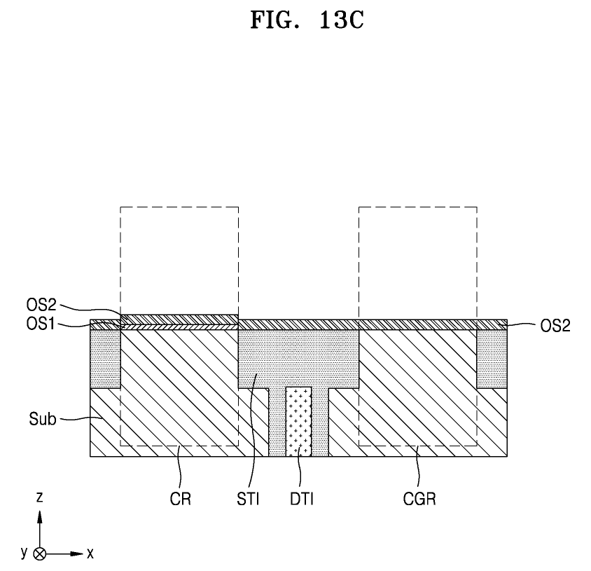

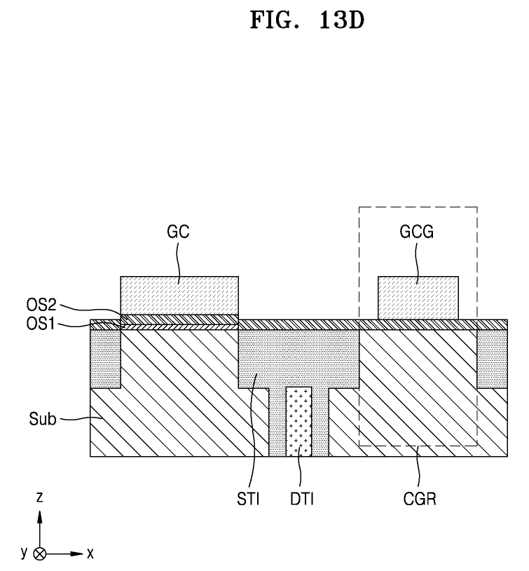

FIGS. 13A, 13B, 13C and 13D are cross-sectional views illustrating a method of manufacturing a capacitor and a dual conversion gain transistor, according to one or more embodiments.

In one or more embodiments, FIGS. 13A to 13D are cross-sectional views illustrating a method for manufacturing the capacitor and the dual conversion gain transistor shown in FIG. 4.

Referring to FIG. 13A, the STI region STI and the DTI region DTI may be formed on the semiconductor substrate Sub. A first insulator layer OS1 may be formed on the semiconductor substrate Sub. In one or more embodiments, the first insulator layer OS1 may be the oxide film, but is not limited thereto.

Referring to FIG. 13B, a photoresist PR1 covering an upper portion of a region CR where a capacitor is to be formed may be applied, and etching may be performed based on the photoresist PR1. In one or more embodiments, the etching may be formed by a wet etching process or a dry etching process.

Referring to FIG. 13C, the photoresist PR1 may be removed and the second insulator layer OS2 may be formed additionally. Through the process steps of FIGS. 13B and 13C, a thickness of the insulator in the region CR where the capacitor is to be formed may be formed differently from a thickness of the insulator of a region CGR where the dual conversion gain transistor is to be formed. In one or more embodiments, the thickness of the insulation in the region CR where the capacitor is to be formed may be greater than a thickness of the insulator in the region CGR where the dual conversion gain transistor is to be formed.

In one or more embodiments, the thickness of the insulator in the region CR where the capacitor is to be formed may correspond to a thickness of the first insulator layer OS1 and a thickness of a second insulator layer OS2, and the thickness of the insulator in the region CGR where the dual conversion gain transistor is to be formed may correspond to the thickness of the second insulator layer OS2. In one or more embodiments, each of the first insulator layer OS1 and the second insulator layer OS2 of the region CR where the capacitor is to be formed may correspond to the first insulator O1 and the second insulator O2 of FIG. 4, and a second insulator layer OS2 of the region CGR where the dual conversion gain transistor is to be formed may correspond to the third insulator O3 of FIG. 4.

Referring to FIG. 13D, the capacitor and the dual conversion gain transistor which have different insulator thicknesses may be manufactured by respectively forming a gate electrode GC in the upper portion of the region CR where the capacitor is to be formed and a gate electrode GCG in an upper portion of the region CGR where the dual conversion gain transistor is to be formed.

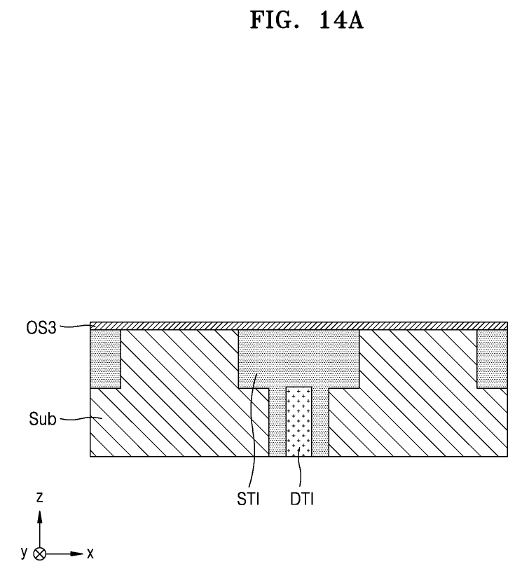

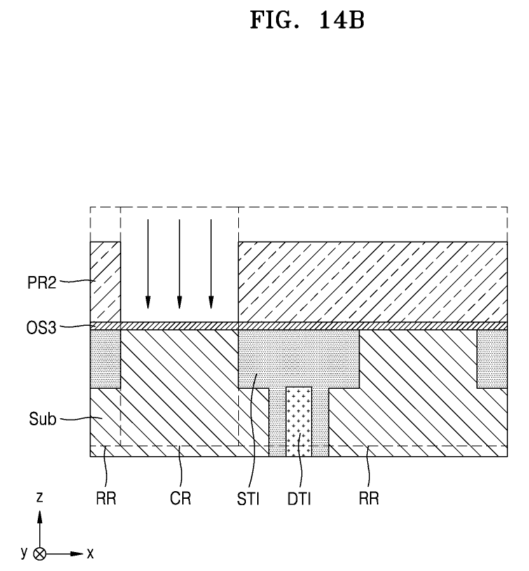

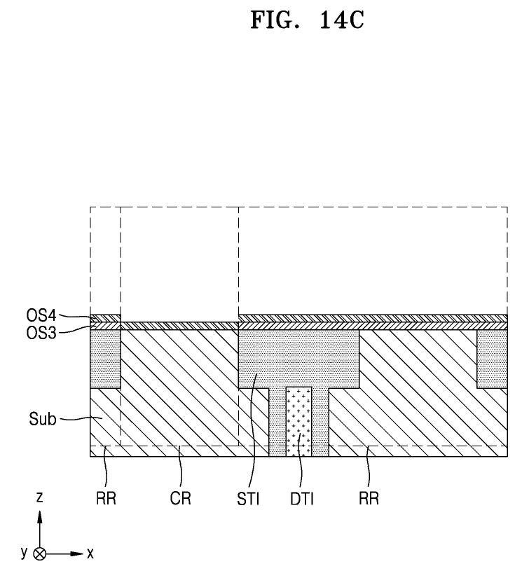

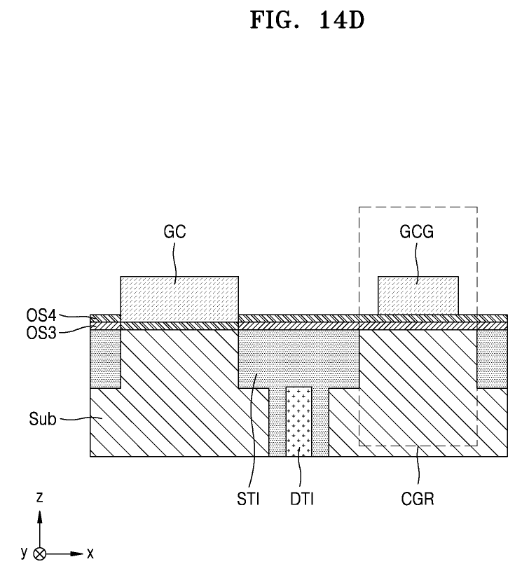

FIGS. 14A, 14B, 14C and 14D are cross-sectional views illustrating a method of manufacturing a capacitor and a dual conversion gain transistor according to one or more embodiments.

In one or more embodiments, FIGS. 14A to 14D are cross-sectional views illustrating a method of manufacturing the capacitor and the dual conversion gain transistor shown in FIG. 5.

Referring to FIG. 14A, the STI region STI and the DTI region DTI may be formed on the semiconductor substrate Sub. A third insulator layer OS3 may be formed on the semiconductor substrate Sub. In one or more embodiments, the third insulator layer OS3 may be the oxide film, but embodiments are not limited thereto.

Referring to FIG. 14B, a photoresist PR2 covering an upper portion of the remaining region RR excluding the region CR where the capacitor is to be formed may be applied, and etching may be performed based on the photoresist PR2. In one or more embodiments, the etching may be formed by the wet etching process or the dry etching process.

Referring to FIG. 14C, the photoresist PR2 may be removed and a fourth insulator layer OS4 may be formed additionally. Through the process steps of FIGS. 14B and 14C, the thickness of the insulator in the region CR where the capacitor is to be formed may be formed differently from a thickness of the insulator in the remaining region RR. In one or more embodiments, the thickness of the insulator in the region CR where the capacitor is to be formed may be smaller than the thickness of the insulator in the remaining region RR.

In one or more embodiments, the thickness of the insulator in the region CR where the capacitor is to be formed may correspond to a thickness of the fourth insulator layer OS4, and the thickness of the insulator in the remaining region RR may correspond to a thickness of the third insulator layer OS3 and the fourth insulator layer OS4 added together. In one or more embodiments, the fourth insulator layer OS4 of the region CR where the capacitor is to be formed may correspond to the fourth insulator O4 of FIG. 5, and the third insulator layer OS3 and the fourth insulator layer OS4 of the remaining region RR may correspond to the fifth insulator O5 and the sixth insulator O6 of FIG. 5.

Referring to FIG. 14D, the gate electrode GC is formed in the region CR where a capacitor is to be formed, and the gate electrode GCG is formed in the upper portion of the region CGR where the dual conversion gain transistor is to be formed among the remaining regions RR, thereby manufacturing the capacitor and the dual conversion gain transistor which have different insulator thicknesses from each other.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An image sensor comprising:
a plurality of pixels,
wherein each of the plurality of pixels comprises:
a plurality of photodiodes;
a plurality of transfer transistors;
a floating diffusion region sharing the plurality of photodiodes and the plurality of transfer transistors;
a dual conversion gain transistor connected to the floating diffusion region; and
a capacitor connected to one end of the dual conversion gain transistor,
wherein the capacitor comprises a first insulator,
wherein the dual conversion gain transistor comprises a second insulator, and
wherein, in a first direction, a first thickness of the first insulator of the capacitor is different from a second thickness of the second insulator of the dual conversion gain transistor.

2. The image sensor of claim 1, wherein the capacitor comprises a metal-oxide semiconductor (MOS) capacitor.

3. The image sensor of claim 2, wherein the first thickness of the first insulator is greater than the second thickness of the second insulator.

4. The image sensor of claim 3, wherein the capacitor further comprises a third insulator on the first insulator.

5. The image sensor of claim 4, wherein a third thickness of the third insulator is the same as the second thickness of the second insulator.

6. The image sensor of claim 5, wherein the dual conversion gain transistor further comprises a fourth insulator under the second insulator in the first direction, and
wherein a fourth thickness of the fourth insulator is less than the first thickness of the first insulator.

7. The image sensor of claim 2, wherein the first thickness of the first insulator is less than the second thickness of the second insulator.

8. The image sensor of claim 7, wherein the dual conversion gain transistor further comprises a third insulator on the second insulator.

9. The image sensor of claim 8, wherein the first thickness of the first insulator is the same as a third thickness of the third insulator.

10. The image sensor of claim 9, wherein the capacitor further comprises a fourth insulator under the first insulator, and
wherein a fourth thickness of the fourth insulator is less than the second thickness of the second insulator.

11. The image sensor of claim 2, wherein the MOS capacitor comprises a vertical transfer gate structure.

12. The image sensor of claim 2, wherein the MOS capacitor comprises a fin field-effect (finFET) structure.

13. The image sensor of claim 2, wherein the MOS capacitor comprises a substrate comprising a well region doped with a first conductive type.

14. An image sensor comprising:
a plurality of sub-pixels;
a floating diffusion region sharing the plurality of sub-pixels; and
a pixel circuit connected to the floating diffusion region, the pixel circuit configured to control a conversion gain of the floating diffusion region, reset the floating diffusion region, and output charges stored in the floating diffusion region,
wherein the pixel circuit comprises:
at least one capacitor connected to the floating diffusion region and comprising at least one first insulator; and
at least one dual conversion gain transistor comprising at least one second insulator, and
wherein, in a first direction, a thickness of the at least one first insulator is different from a thickness of the at least one second insulator.

15. The image sensor of claim 14, wherein the at least one dual conversion gain transistor comprises:
a first dual conversion gain transistor connected in series with the floating diffusion region;
a second dual conversion gain transistor connected to one end of the first dual conversion gain transistor;
wherein the at least one capacitor comprises:
a first capacitor connected between the first dual conversion gain transistor and the second dual conversion gain transistor; and
a second capacitor connected to one end of the second dual conversion gain transistor,
wherein the at least one first insulator comprises a third insulator corresponding to the first capacitor, and a fourth insulator corresponding to the second capacitor,
wherein the at least one second insulator comprises a fifth insulator corresponding to the first dual conversion gain transistor and a sixth insulator corresponding to the second dual conversion gain transistor, and
wherein, in the first direction, thicknesses of the fifth insulator and the sixth insulator are different from thicknesses of the third insulator and the fourth insulator.

16. The image sensor of claim 15, wherein the thickness of the third insulator of the first capacitor is same as the thickness of the fourth insulator of the second capacitor.

17. The image sensor of claim 15, wherein the thickness of the third insulator of the first capacitor is greater than the thickness of the fourth insulator of the second capacitor.

18. The image sensor of claim 15, wherein the thickness of the third insulator of the first capacitor is less than the thickness of the fourth insulator of the second capacitor.

19. An image sensor comprising:
a substrate having a first surface and a second surface opposite to the first surface in a first direction;
a metal-oxide semiconductor (MOS) capacitor on the second surface of the substrate; and
a dual conversion gain transistor on the substrate,
wherein the MOS capacitor and the dual conversion gain transistor are configured to control a conversion gain of a floating diffusion region of a pixel, and
wherein the MOS capacitor comprises:
a first insulator on the substrate; and
a first gate electrode on the first insulator,
wherein the dual conversion gain transistor comprises:
a second insulator on the substrate; and
a second gate electrode on the second insulator, and
wherein, in the first direction, a thickness of the first insulator is different from a thickness of the second insulator.

20. The image sensor of claim 19, wherein at least one of the first insulator and the second insulator are provided as an insulator structure comprising a plurality of insulators.
